(19) United States
(12) Patent Application Publication
(10) Pub. No.: US 2014/0346512 A1
(43) Pub. Date: Nov. 27, 2014

(54) SEMICONDUCTOR INTEGRATED CIRCUIT DEVICE

(71) Applicant: DENSO CORPORATION, Kariya-city (JP)

(72) Inventor: Takatoshi NOMURA, Kariya-city (JP)

(73) Assignee: DENSO CORPORATION, Kariya-city (JP)

(21) Appl. No.: 14/277,890

(22) Filed: May 15, 2014

(30) Foreign Application Priority Data
May 21, 2013 (JP) 2013-107049
Feb. 26, 2014 (JP) 2014-035308

(51) Int. Cl. H01L 23/58

(52) U.S. Cl. CPC H01L 23/58
USPC 257/48

(57) ABSTRACT

In a semiconductor integrated circuit device, a target chip, a test chip, and an electronic device are incorporated in a package. A signal terminal of the target chip is a target terminal and to be subjected to a test. The test chip has a test mechanism for allowing the test to be performed through an external terminal exposed outside the package. In a product operation mode where the semiconductor integrated circuit device operates as a product, the electronic device is connected to the target terminal. The test chip includes a common wire connected to the test terminal, a first terminal connected to the target terminal, a first switch for opening and closing a connection between the common wire and the first terminal, a second terminal connected to the electronic device, and a second switch for opening and closing a connection between the first terminal and the second terminal.

### CROSS REFERENCE TO RELATED APPLICATION

This application is based on Japanese Patent Application No. 2013-107049 filed on May 21, 2013 and No. 2014-35308 filed on Feb. 26, 2014, the contents of which are incorporated herein by reference.

### FIELD

The present disclosure relates to a semiconductor integrated circuit device having multiple semiconductor chips incorporated in a single package.

### BACKGROUND

Multi chip package (MCP) and system in package (SIP) have been known as modularization technologies for mounting (i.e., incorporating) multiple semiconductor chips in a single package to reduce the footprint. Further, in recent years, discrete devices outside the chips have been incorporated in the package.

This approach may allow the package to be easily mounted in an apparatus. However, since there has been a constant demand for a reduction in size of such a modularized product, it is difficult to expose all signal terminals outside the package. To ensure quality of the product, some technologies have been proposed that allow all of the signal terminals to undergo an electrical test even when the number of external terminals is small.

In a technology disclosed in JP-A-2007-163454 corresponding to US 2007/0108998A1, a test switch is added to a semiconductor chip (hereinafter sometimes referred to as the “target chip”) which is to be subjected to an electrical test, and each signal terminal is tested through a small number of external terminals by switching between a probe terminal and a non-probe terminal using the switch. In a technology disclosed in JP-A-2009-079920, such a test switch is added to a semiconductor chip which is connectable to and different from a target chip to be subjected to an electrical test, and each signal terminal of the target chip is tested through external terminals using the test switch.

The above conventional technologies are silent about a structure where electronic devices (La, discrete devices) outside chips are incorporated in a package. Assuming that an electronic device (e.g., passive device including a resistor and a capacitor or an active device including a transistor and an IC) is connected to a signal terminal (La, pad) of a target chip to be subjected to an electrical test, the electrical test may be affected by the electronic device. Therefore, the above conventional technologies may not correctly perform the electrical test. For example, the electrical test may be affected by a resistor causing a reduction in an application voltage, a capacitor causing a delay in test time, and a transistor or an IC causing a high-impedance state.

### SUMMARY

In view of the above, it is an object of the present disclosure to provide a semiconductor integrated circuit device in which multiple chips and an electronic device outside the chips are incorporated in a single package in such a manner that a signal terminal of a target chip which is to be subjected to a test is capable of undergoing the test correctly without being affected by the electronic device.

According to an aspect of the present disclosure, a semiconductor integrated circuit device includes a package, semiconductor chips, an electronic device, and an external terminal. The semiconductor chips are incorporated in the package and have signal terminals connected to each other inside the package. The electronic device is incorporated in the package. The external terminal extends from inside to outside the package. The semiconductor chips include a target chip and a test chip. The signal terminal of the target chip is a target terminal which is to be subjected to a test. The test chip has a test mechanism capable of allowing the test to be performed through the external terminal. In a product operation mode where the semiconductor integrated circuit device operates as a product, a terminal of the electronic device is connected to the target terminal.

As the test mechanism, the test chip includes a common wire, a first terminal, a first switch, a second terminal, a second switch, and a controller. The common wire is connected to the test terminal. The first terminal of the test chip is connected to the target terminal. The first switch opens and closes a connection between the common wire and the first terminal of the test chip. The second terminal of the test chip is connected to the first terminal of the electronic device. The second switch opens and closes a connection between the first terminal of the test chip and the second terminal of the test chip. The controller controls the first switch and the second switch.

When the first switch is OFF and the second switch is ON, the target terminal is connected to the terminal of the electronic device through the first terminal, the second switch, and the second terminal. Thus, in the product operation mode, the target chip and the electronic device are connected in a manner as originally intended so that the semiconductor integrated circuit device can provide desired performance as a product.

In contrast, when the first switch is ON and the second switch is OFF, the target terminal is connected to the external terminal through the first terminal and the common wire in such a manner that the target terminal and the terminal of the electronic device are electrically isolated from each other by the second switch. Thus, the target terminal can be tested without being affected by the electronic device while the number of external terminals exposed outside the package is minimized.

### BRIEF DESCRIPTION OF THE DRAWINGS

The above and other objects, features and advantages of the present disclosure will become more apparent from the following detailed description made with reference to the accompanying drawings. In the drawings:

FIG. 1 is a schematic diagram of a semiconductor integrated circuit device according to a first embodiment of the present disclosure;

FIG. 2 is a schematic diagram of a semiconductor integrated circuit device according to a second embodiment of the present disclosure;

FIG. 3 is a schematic diagram of a semiconductor integrated circuit device according to a third embodiment of the present disclosure;

FIG. 4 is a schematic diagram of a semiconductor integrated circuit device according to a fourth embodiment of the present disclosure;

FIG. 5 is a schematic diagram of a semiconductor integrated circuit device according to a first example of a fifth embodiment of the present disclosure;

FIG. 6 is a schematic diagram of a semiconductor integrated circuit device according to a second example of the fifth embodiment;

FIG. 7 is a schematic diagram of a semiconductor integrated circuit device according to a third example of the fifth embodiment;

FIG. 8 is a schematic diagram of a semiconductor integrated circuit device according to a first example of a sixth embodiment of the present disclosure;

FIG. 9 is a schematic diagram of a semiconductor integrated circuit device according to a second example of the sixth embodiment;

FIG. 10 is a schematic diagram of a semiconductor integrated circuit device according to a third example of the sixth embodiment;

FIG. 11 is a schematic diagram of a semiconductor integrated circuit device according to a seventh embodiment of the present disclosure;

FIG. 12 is a schematic diagram for explaining an electronic device test performed in the semiconductor integrated circuit device according to the seventh embodiment;

FIG. 13 is a schematic diagram for explaining a leak test conducted in the semiconductor integrated circuit device according to the seventh embodiment;

FIG. 14 is a schematic diagram of a semiconductor integrated circuit device according to an eighth embodiment of the present disclosure;

FIG. 15 is a schematic diagram for explaining an electronic device test performed in the semiconductor integrated circuit device according to the eighth embodiment;

FIG. 16 is a schematic diagram for explaining a leak test conducted in the semiconductor integrated circuit device according to the eighth embodiment; and

FIG. 17 is a schematic diagram of a semiconductor integrated circuit device according to a ninth embodiment of the present disclosure.

### DETAILED DESCRIPTION

Embodiments of the present disclosure are described below with reference to the drawings, in which the same characters refer to the same or corresponding parts. Throughout the embodiments, the term “connect” can include both direct connection and indirect connection through a wire or the like unless otherwise noted.

### First Embodiment

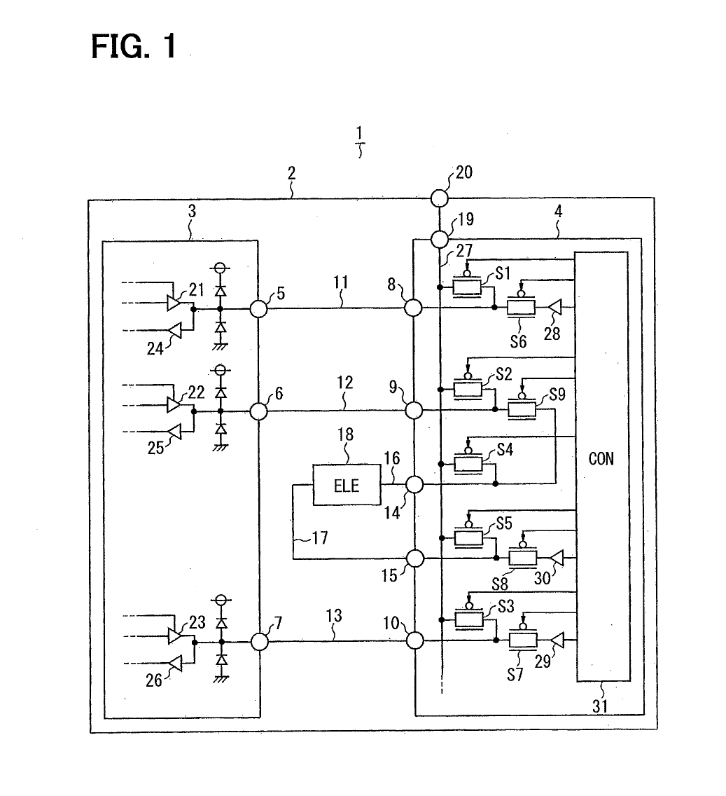

A semiconductor integrated circuit device 1 according to a first embodiment of the present disclosure is described below with reference to FIG. 1. As shown in FIG. 1, the semiconductor integrated circuit device 1 is configured as a system-in-package (SiP) and has multiple semiconductor chips incorporated in a single package 2. In FIG. 1, portions unrelated to the present disclosure are not shown. According to the first embodiment, the semiconductor integrated circuit device 1 has two semiconductor chips 3 and 4. Examples of the semiconductor chips 3 and 4 can include a microcomputer and a custom chip for implementing functions a user wants.

Inside the package 2, pads 5, 6, and 7 of the semiconductor chip 3 are connected to pads 8, 9, and 10 of the semiconductor chip 4 through inter-chip wires 11, 12, and 13, respectively. An electronic device 18 is connected between the pads 14 and 15 of the semiconductor chip 4 through wires 16 and 17. In this case, a first terminal of the electronic device 18 is connected to the pad 14, and a second terminal of the electronic device 18 is connected to the pad 15. For example, the electronic device 18 can be a resistor. In a product operation mode where the semiconductor integrated circuit device 1 operates as a product, the electronic device 18 needs to be connected in series between the pad 6 of the semiconductor chip 3 and the pad 15 of the semiconductor chip 4.

According to the first embodiment, the pads 5, 6, and 7 of the semiconductor chip 3 are to be subjected to an electrical test. The semiconductor chip 3 corresponds to a target chip recited in claims, and the pads 5, 6, and 7 correspond to target terminals recited in claims. The semiconductor chip 4 has a test mechanism capable of performing an electrical test of the pads 5, 6, and 7 of the semiconductor chip 3. The semiconductor chip 4 corresponds to a test chip recited in claims. The semiconductor chip 4 has a test pad 19 used for the test. The semiconductor integrated circuit device 1 has an external test terminal 20 used for the test. The external test terminal 20 is connected to the test pad 19 of the semiconductor chip 4 and extends from inside to outside the package 2.

Next, internal circuitry of the semiconductor chip 3 is described. Inside the semiconductor chip 3, the pads 5, 6, and 7 are connected to output terminals of output buffers 21, 22, and 23 and input terminals of input buffers 24, 25, and 26, respectively. The output buffers 21, 22, and 23 output data, which are received from internal circuits (not shown), to external circuits (not shown) outside the semiconductor chip 3 through the pads 5, 6, and 7, respectively. The input buffers 24, 25, and 26 input data, which are received from external circuits (not shown) outside the semiconductor chip 3, to internal circuits (not shown) through the pads 5, 6, and 7, respectively. Inside the semiconductor chip 3, the pads 5, 6, and 7 are separately connected to protection circuits with diodes.

Next, internal circuitry of the semiconductor chip 4 is described. Inside the semiconductor chip 4, the pads 8, 9, 10, 14, and 15 are connected to a common wire 27 through switches S1, S2, S3, 54, and S5, respectively. The common wire 27 is connected to the test pad 19. Inside the semiconductor chip 4, the pads 8, 10, and 15 are connected to output terminals of output buffers 28, 29, and 30 through switches S6, S7, and S8, respectively. The pads 8, 10, and 15 correspond to signal terminals recited in claims. The output buffers 28, 29, and 30 output data, which are received from a control circuit 31, to external circuits (not shown) outside the semiconductor chip 4 through the pads 8, 10, and 15, respectively. Inside the semiconductor chip 4, the pads 9 and 14 are connected to each other through a switch S9.

The switches S1-S9 are analog switches. The switches S1-S9 are turned ON and OFF in accordance with switching signals received from the control circuit 31. That is, the control circuit 31 controls operations of the switches S1-S9. The control circuit 31 corresponds to a controller recited in claims. Correspondence between terms used in the first embodiment and claims is as follows. The pad 9 corresponds to a first terminal, the pad 14 corresponds to a second terminal, the switch S2 corresponds to a first switch, the switch S9 corresponds to a second switch, the switch S4 corresponds to a third switch, the switch 55 corresponds to a fourth switch, and the switch S8 corresponds to a fifth switch.

Next, operation modes of the semiconductor integrated circuit device 1 are described.

(1) A mode (product operation mode) to cause the semiconductor integrated circuit device 1 to operate as a product

When the semiconductor integrated circuit device 1 operates as a product, the control circuit 31 controls the switches S1-S9 as follows: The control circuit 31 turns OFF all the switches S1-S5 connected to the common wire 27 while turning ON the switch S9. Further, the control circuit 31 turns ON and OFF the switches S6-S8 as needed.

(2) A mode to perform an electrical test through a pad which is disconnected from the electronic device 18.

When an electrical test is performed through the pad 5, the control circuit 31 controls the switches S1-S9 as follows: The control circuit 31 turns ON the switch S1 while turning OFF the switch S6. Further, the control circuit 31 turns OFF all the remaining switches S2-S5 connected to the common wire 27. In this case, each of the switches S7, S8, and 39 can be either ON or OFF.

When an electrical test is performed through the pad 7, the control circuit 31 controls the switches S1-S9 as follows: The control circuit 31 turns ON the switch S3 while turning OFF the switch S7. Further, the control circuit 31 turns OFF all the remaining switches S1, S2, 54, and 35 connected to the common wire 27. In this case, each of the switches S6, S8, and S9 can be either ON or OFF.

(3) A mode to perform an electrical test through a pad which is connected to the electronic device 18

When an electrical test is performed through the pad 6, which is connected to the first terminal of the electronic device 18 when the semiconductor integrated circuit device 1 operates as a product, the control circuit 31 controls the switches S1-S9 as follows: The control circuit 31 turns ON the switch S2 while turning OFF the switch S9. Further, the control circuit 31 turns OFF all the remaining switches S1, and S3-S5 connected to the common wire 27. In this case, each of the switches S6-S8 can be either ON or OFF.

(4) A Mode to Perform an Electrical Test of the Electronic Device 18

When an electrical test is performed through the first terminal of the electronic device 18, the control circuit 31 controls the switches S1-S9 as follows: The control circuit 31 turns ON the switch S4 while turning OFF the switch S9. Further, the control circuit 31 turns OFF all the remaining switches S1-S3, and S5 connected to the common wire 27. In this case, the switch S8 can be turned ON and OFF according to the contents of the test. Each of the switches S6 and S7 can be either ON or OFF.

When an electrical test is performed through the second terminal of the electronic device 18, the control circuit 31 controls the switches S1-S9 as follows: The control circuit 31 turns ON the switch S5 while turning OFF the switch S8. Further, the control circuit 31 turns OFF all the remaining switches S1-S4 connected to the common wire 27. In this case, the switch S9 can be turned ON and OFF according to the contents of the test. Each of the switches S6 and S7 can be either ON or OFF.

Next, advantages of the first embodiment are described.

When the semiconductor integrated circuit device 1 operates as a product, the control circuit 31 controls the switches S1-S9 as described in the above section (1). Accordingly, the pad 6 of the semiconductor chip 3 is connected to the first terminal of the electronic device 18 through the wire 12, the pad 9, the switch S9, the pad 14, and the wire 16. Thus, in the product operation mode, the semiconductor chip 3, the semiconductor chip 4, and the electronic device 18 are connected in a manner as originally intended so that the semiconductor integrated circuit device 1 can provide desired performance as a product.

When an electrical test is performed through the pad 6 which is connected to the first terminal of the electronic device 18 in the product operation mode, the control circuit 31 controls the switches S1-S9 as described in the above section (3). Accordingly, the pad 6 is connected to the external test terminal 20 through the wire 12, the pad 9, the switch S2, the common wire 27, and the test pad 19. In this case, since the switch S2 is OFF, the pad 6 is electrically isolated from the first terminal of the electronic device 18. Therefore, an electrical test of a current path from the external test terminal 20 to the pad 6 can be performed without being affected by the electronic device 18.

When an electrical test is performed through the pad 5 or 7 which is disconnected from the electronic device 18 in the product operation mode, the control circuit 31 controls the switches S1-S9 as described in the above section (2). Accordingly, the pad 5 or 7 is connected to the external test terminal 20 through the common wire 27 and the test pad 19, and the like. Therefore, an electrical test of a current path from the external test terminal 20 to the pad 5 or 7 can be performed. In this way, according to the first embodiment, the number of the terminals exposed outside the package 2 can be minimized, and an electrical test of the pad of the semiconductor chip 3 as a target chip can be property performed without being affected by the electronic device 18 which is incorporated in the package 2.

Further, since the control circuit 31 controls the switches S1-S9 as described in the above section (4), a voltage or a current can be applied to each terminal of the electronic device 18, and a state of each terminal of the electronic device 18 can be monitored. Thus, according to the first embodiment, various types of tests can be applied to the electronic device 18. Further, the switch S9 is OFF when a voltage or a current is applied to the first terminal of the electronic device 18. Thus, a voltage or a current is not applied to the pad 6 of the semiconductor chip 3. Therefore, the tests can be performed by applying a voltage or a current to the electronic device 18 even when application of a voltage or a current to the pad 6 (and internal circuits connected to the pad 6) is prohibited.

### Second Embodiment

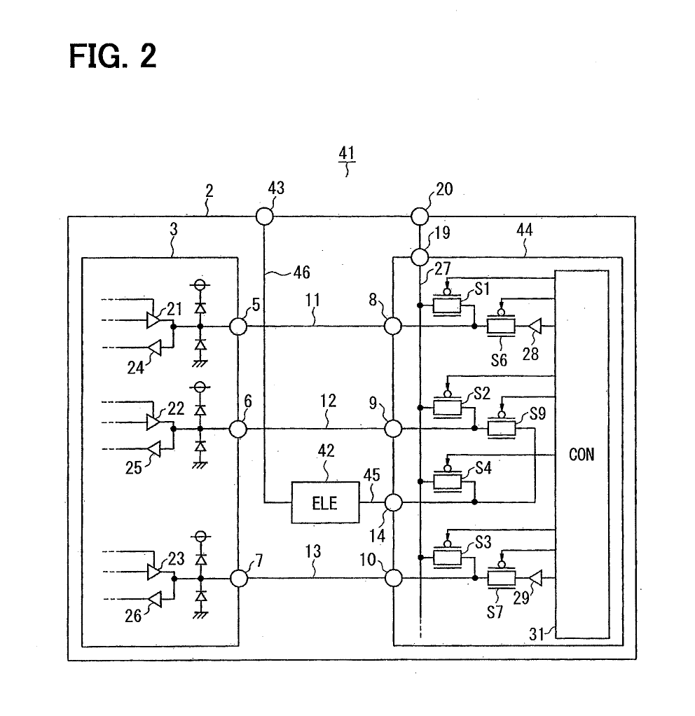

A semiconductor integrated circuit device 41 according to a second embodiment of the present disclosure is described below with reference to FIG. 2. The semiconductor integrated circuit device 41 of the second embodiment differs from the semiconductor integrated circuit device 1 of the first embodiment as follows.

The semiconductor integrated circuit device 41 has an electronic device 42 instead of the electronic device 18 and a semiconductor chip 44 instead of the semiconductor chip 4 as a test chip. Further, the semiconductor integrated circuit device 41 has an additional external terminal 43 extending from the inside to the outside of the package 2.

For example, the electronic device 42 can be a capacitor. In a product operation mode where the semiconductor integrated circuit device 41 operates as a product, the electronic device 42 needs to be connected in series between the pad 6 of the semiconductor chip 3 and the external terminal 43. A first terminal of the electronic device 42 is connected to the pad 14 through a wire 45. A second terminal of the electronic device 42 is connected to the external terminal 43 through a wire 46. The semiconductor chip 44 differs from the semiconductor chip 4 in that it does not have the pad 15, the switches S5 and S8, and the output buffer 30.

In the second embodiment, the control circuit 31 controls the switches S1-S4, S6, S7, and S9 in the same manner as in the first embodiment. Thus, the same advantages as in the first embodiment can be obtained in the second embodiment except for when the test is performed through the second terminal of the electronic device 42. Since the second terminal of the electronic device 42 is connected to the external terminal 43 exposed outside the package 2, the test can be performed through the second terminal of the electronic device 42 by using the external terminal 43.

### Third Embodiment

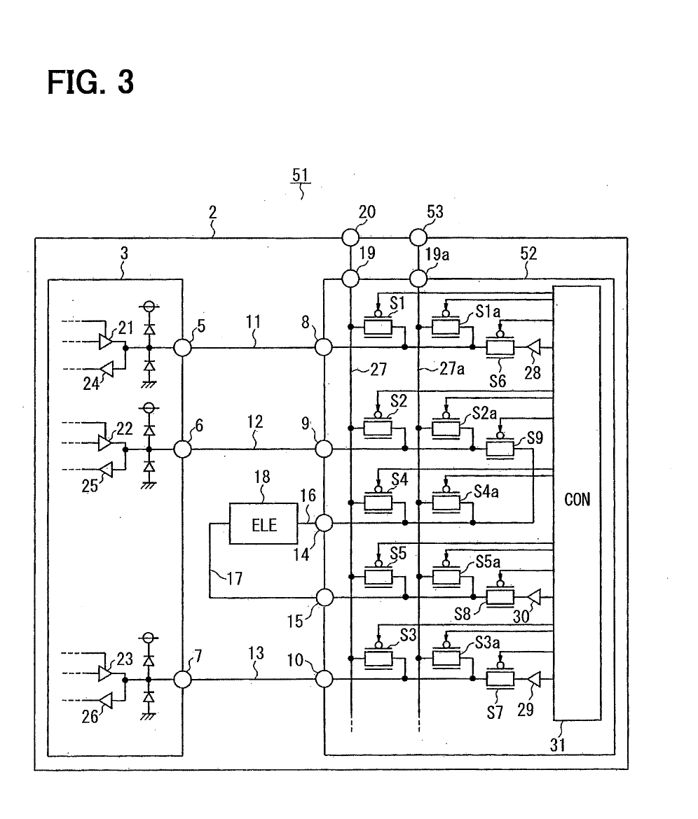

A semiconductor integrated circuit device 51 according to a third embodiment of the present disclosure is described below with reference to FIG. 3. The semiconductor integrated circuit device 51 of the third embodiment differs from the semiconductor integrated circuit device 1 of the first embodiment as follows.

The semiconductor integrated circuit device 51 has a semiconductor chip 52 instead of the semiconductor chip 4 as a test chip. Further, the semiconductor integrated circuit device 51 has an additional external test terminal 53.

The semiconductor chip 52 differs from the semiconductor chip 4 in that it further has a test pad 19a, a common wire 27a, and switches S1a, S2a, S1a, S4a, and S5a. Inside the semiconductor chip 52, the pads 8-10, 14, and 15 are connected to the common wire 27a through the switches S1a-S5a, respectively. The common wire 27a is connected to the test pad 19a. The test pad 19a is connected to the external test terminal 53. Correspondence between terms used in the third embodiment and claims is as follows. The switch S2a corresponds to a first switch, the switch S9a corresponds to a second switch, the switch S4a corresponds to a third switch, the switch S5a corresponds to a fourth switch, and the switch S8a corresponds to a fifth switch.

The switches S1a-S5a are analog switches. The switches S1a-S5a are turned ON and OFF in accordance with switching signals received from the control circuit 31. The control circuit 31 turns OFF all the switches S1a-S5a when the semiconductor integrated circuit device 51 is in any of the modes described in the first embodiment. Thus, the same advantages as in the first embodiment can be obtained in the third embodiment.

In addition, according to the third embodiment, each pad of the semiconductor chip 52 is connected to the two external test terminals 20 and 53 through the two common wires 27 and 27a. Therefore, voltage or current signals applied to any two of the pads of the semiconductor chip 52 through the external test terminals 20 and 53 can be different from each other. Thus, as described below, a leak test between pads can be performed, and a characteristic/functional test for the electronic device 18 can be performed.

(1) A Mode to Perform a Leak Test Between Pads

When the leak test between the pads 8 and 9 is performed, the control circuit 31 controls the switches as follows: The control circuit 31 turns ON the switches S1 and S2a (or S1a and S2) while turning OFF all the remaining switches connected to the common wires 27 and 27a. Besides, the control circuit 31 turns OFF the switches Se and S9. In this case, each of the switches S7 and S8 can be either ON or OFF.

Under this condition, a current flowing between the external test terminals 20 and 53 is measured by applying a high voltage (e.g., 5V) to one of the external test terminals 20 and 53 while applying a low voltage (e.g., 0V) to the other of the external test terminals 20 and 53. Thus, a leak test for testing a leak current between the pads 8 and 9, between the wires 11 and 12, and between the pads 5 and 6 can be performed.

(2) A Mode to Perform a Characteristic/Functional Test for the Electronic Device 18

Examples of the characteristic/functional test for the electronic device 18 can include a test for input and output characteristics of the electronic device 18 and a test for a resistance of the electronic device 18. When the characteristic/functional test for the electronic device 18 is performed, the control circuit 31 controls the switches as follows: The control circuit 31 turns ON the switches S4 and S5a (or S4a and S5) while turning OFF all the remaining switches connected to the common wires 27 and 27a. Besides, the control circuit 31 turns OFF the switches S8 and S9. In this case, each of the switches S6 and S7 can be either ON or OFF.

Under this condition, the test for input and output characteristics of the electronic device 18 can be performed by measuring an output signal appearing at one of the external test terminals 20 and 53 while applying an input signal to the other of the external test terminals 20 and 53.

Alternatively, under this condition, the test for the resistance of the electronic device 18 can be performed as follows. A current flowing between the external test terminals 20 and 53 is measured by applying a high voltage (e.g., 5V) to one of the external test terminals 20 and 53 while applying a low voltage (e.g., 0V) to the other of the external test terminals 20 and 53. Then, a resistance of the electronic device 18 is calculated based on the applied voltages and the measured current.

### Fourth Embodiment

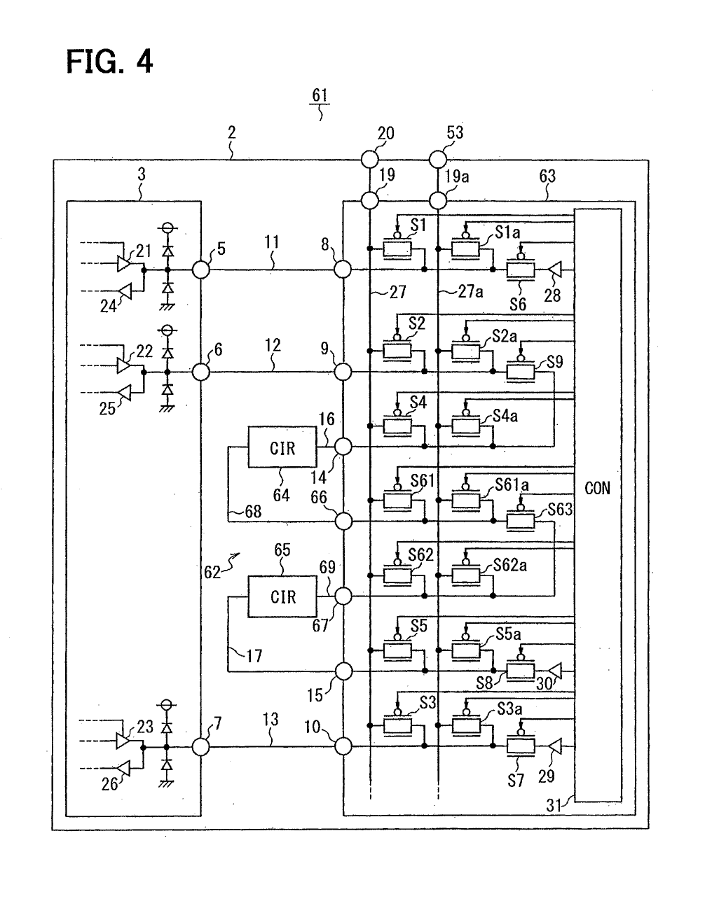

In the preceding embodiments, the electronic device having the first terminal to be connected to the target pad is a single circuit element. Alternatively, as shown in FIG. 4, the electronic device can have multiple circuit elements connected in series.

FIG. 4 shows a semiconductor integrated circuit device 61 according to a fourth embodiment of the present disclosure. The semiconductor integrated circuit device 61 of the fourth embodiment differs from the semiconductor integrated circuit device 51 of the third embodiment as follows.

The semiconductor integrated circuit device 61 has an electronic device 62 instead of the electronic device 18 and a semiconductor chip 63 instead of the semiconductor chip 52 as a test chip. The electronic device 62 has two circuit elements 64 and 65. In the product operation mode where the semiconductor integrated circuit device 61 operates as a product, the circuit elements 64 and 65 need to be connected in series between the pad 6 of the semiconductor chip 3 and the pad 15 of the semiconductor chip 63. The semiconductor chip 63 differs from the semiconductor chip 52 in that it further has pads 66 and 67 and switches S61, S62, S63, S61a, and S62a.

The circuit element 64 is connected between the pads 14 and 66 through the wires 16 and 68. The circuit element 65 is connected between the pads 67 and 15 through the wires 69 and 17. Inside the semiconductor chip 63, the pads 63 and 67 are connected to the common wire 27 through the switches S61 and S62, respectively, and connected to the common line 27a through the switches S61a and S62a, respectively. Further, inside the semiconductor chip 63, the pads 66 and 67 are connected to each other through the switch S63. The switches S61-S63, S61a, and S62a are analog switches and are turned ON and OFF in accordance with switching signals received from the control circuit 31. Correspondence between terms used in the fourth embodiment and claims is as follows. The pads 66 and 67 correspond to a third terminal, the switch 863 corresponds to a sixth switch, and the switches S61, S62, S61a, and S62a correspond to a seventh switch.

Thus, according to the fourth embodiment, although the electronic device to be connected to the target pad has multiple circuit elements connected in series, the same advantages as in the third embodiment can be obtained. Further, according to the fourth embodiment, voltage or current signals applied to the pads to be connected to the terminals of the circuit elements 64 and 65 of the electronic device 62 can be made different from each other by switching the switches including the switches S61-S63, S61a, and S62a as needed. Therefore, a characteristic/functional test for the circuit element 64 and a characteristic/functional test for the circuit element 65 can be performed independently of each other.

### Fifth Embodiment

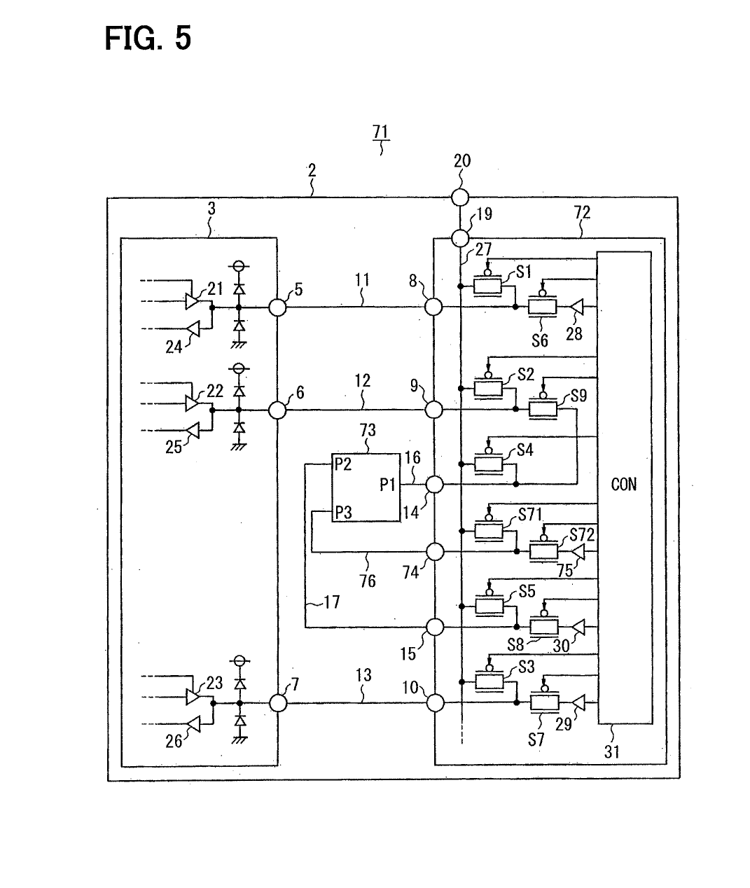

In the preceding embodiments, the electronic device having the first terminal to be connected to the target pad has two terminals, i.e., first and second terminals. Alternatively, as shown in FIGS. 5, 6, and 7, the electronic device can have three or more terminals.

### First Example

FIG. 5 shows a semiconductor integrated circuit device 71 according to a first example of a fifth embodiment of the present disclosure. The semiconductor integrated circuit device 71 differs from the semiconductor integrated circuit device 1 of the first embodiment as follows.

The semiconductor integrated circuit device 71 has an electronic device 73 instead of the electronic device 18 and a semiconductor chip 72 instead of the semiconductor chip 4 as a test chip. The semiconductor chip 72 differs from the semiconductor chip 4 in that it further has a pad 74, a switch S71, a switch S72, and an output buffer 75. In a product operation mode where the semiconductor integrated circuit device 71 operates as a product, the electronic device 73 needs to be connected between one target pad of the semiconductor chip 3 as a target chip and multiple pads of the semiconductor chip 72 as a test chip.

The electronic device 73 has three terminals P1, P2, and P3 and may be a transistor, for example. In the product operation mode, the electronic device 73 needs to be connected between the pad 6 of the semiconductor chip 3 and the pads 15 and 74 of the semiconductor chip 72. The terminal P1 of the electronic device 73 is connected to the pad 14 through the wire 16. The terminal P2 of the electronic device 73 is connected to the pad 15 through the wire 17. The terminal P3 of the electronic device 73 is connected to the pad 74 through a wire 76.

Inside the semiconductor chip 72, the pad 74 is connected to the common wire 27 through the switch S71 and also connected to an output terminal of the output buffer 75 through the switch S72. The switches S71 and S72 are analog switches. The switches S71 and S72 are turned ON and OFF in accordance with switching signals received from the control circuit 31.

Correspondence between terms used in the first example of the fifth embodiment and claims is as follows. The pad 74 corresponds to a signal terminal, the switch S71 corresponds to a fourth switch, the switch S72 corresponds to a fifth switch, the terminal P1 corresponds to a first terminal, and the terminals P2 and P3 correspond to a second terminal.

### Second Example

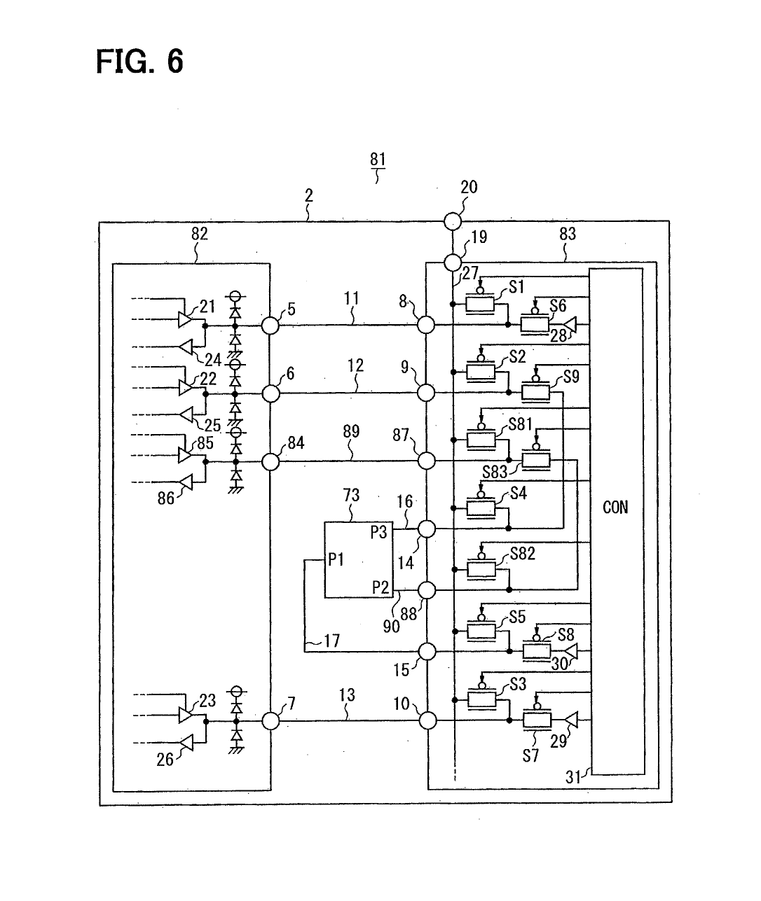

FIG. 6 shows a semiconductor integrated circuit device 81 according to a second example of the fifth embodiment. The semiconductor integrated circuit device 81 differs from the semiconductor integrated circuit device 1 of the first embodiment as follows. The semiconductor integrated circuit device 81 has an electronic device 73 instead of the electronic device 18, a semiconductor chip 82 instead of the semiconductor chip 3 as a target chip, and a semiconductor chip 83 instead of the semiconductor chip 4 as a test chip.

The semiconductor chip 82 differs from the semiconductor chip 3 in that it further has a pad 84, an output buffer 85, and an input buffer 86. Inside the semiconductor chip 82, the pad 84 is connected to an output terminal of the output buffer 85 and an input terminal of the input buffer 86. The semiconductor chip 83 differs from the semiconductor chip 4 in that it further has pads 87 and 88 and switches S81, S82, and S83. The pad 87 is connected to the pad 84 of the semiconductor chip 82 through the wire 89. In a product operation mode where the semiconductor integrated circuit device 81 operates as a product, the electronic device 73 needs to be connected between multiple target pads of the semiconductor chip 82 as a target chip and one pad of the semiconductor chip 83 as a test chip.

The electronic device 73 has three terminals P1, P2, and P3 and may be a transistor, for example. In the product operation mode, the electronic device 73 needs to be connected between the pads 6 and 84 of the semiconductor chip 82 and the pad 15 of the semiconductor chip 83. The terminal P1 of the electronic device 73 is connected to the pad 15 through the wire 17. The terminal P2 of the electronic device 73 is connected to the pad 88 through a wire 90. The terminal P3 of the electronic device 73 is connected to the pad 14 through the wire 16.

Inside the semiconductor chip 83, the pads 87 and 88 are connected to the common wire 27 through the switches S81 and S82, respectively. Further, inside the semiconductor chip 83, the pads 87 and 88 are connected to each other through the switch S83. The switches S81 and S82 are analog switches and turned ON and OFF in accordance with switching signals received from the control circuit 31.

Correspondence between terms used in the second example of the fifth embodiment and claims is as follows. The pad 84 corresponds to a target signal terminal, the pad 87 corresponds to a first terminal, the pad 88 corresponds to a second terminal, the switch S81 corresponds to a first switch, the switch S83 corresponds to a second switch, the switch S82 corresponds to a third switch, the terminal P1 corresponds to a second terminal, and the terminals P2 and P3 correspond to a first terminal.

### Third Example

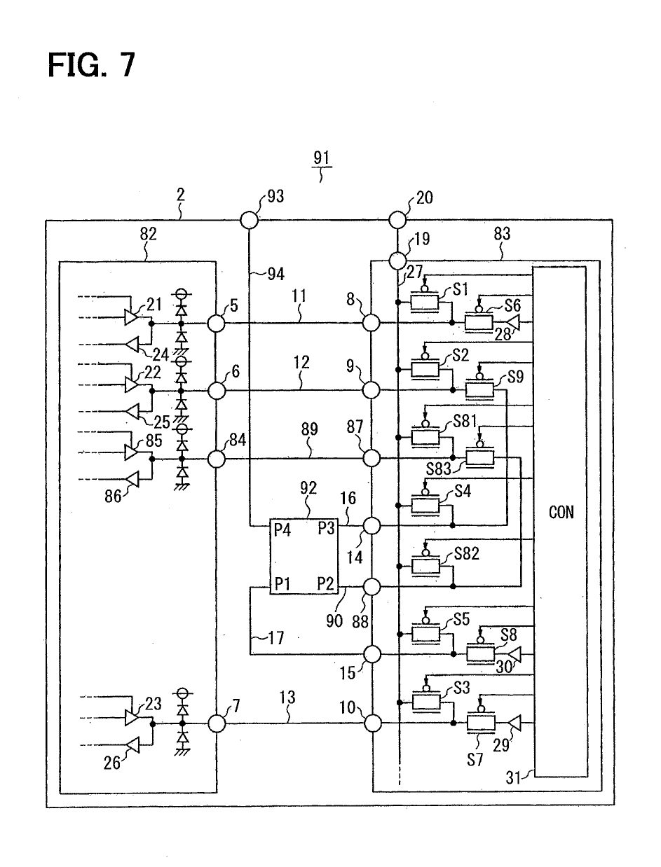

FIG. 7 shows a semiconductor integrated circuit device 91 according to a third example of the fifth embodiment. The semiconductor integrated circuit device 91 differs from the semiconductor integrated circuit device 81 of the second example of the fifth embodiment as follows.

The semiconductor integrated circuit device 91 has an electronic device 92 instead of the electronic device 73 and an additional external terminal 93. In a product operation mode where the semiconductor integrated circuit device 91 operates as a product, the electronic device 92 needs to be connected between multiple target pads of the semiconductor chip 82 as a target chip and a pad of the semiconductor chip 83 as a test chip and the external terminal 93.

The electronic device 92 has four terminals P1, P2, P3, and P4 and may be an IC, for example. In the product operation mode, the electronic device 92 needs to be connected between the pads 6 and 84 of the semiconductor chip 82 and the pad 15 of the semiconductor chip 83 and the external terminal 93. The terminal P4 of the electronic device 92 is connected to the external terminal 93 through a wire 94. Correspondence between terms used in the third example of the fifth embodiment and claims is as follows. The terminals P1 and P4 correspond to a second terminal, and the terminals P2 and P3 correspond to a first terminal.

Thus, according to the fifth embodiment, although the electronic device to be connected to the target pad has three or more terminals, the same advantages as in the first embodiment can be obtained. In the above examples of the fifth embodiment, the number of the terminals of the electronic device is three or four. Even when the electronic device has five or more terminals, the same advantages as in the first embodiment can be obtained by adding corresponding switches in the same manner as discussed in the fifth embodiment.

### Sixth Embodiment

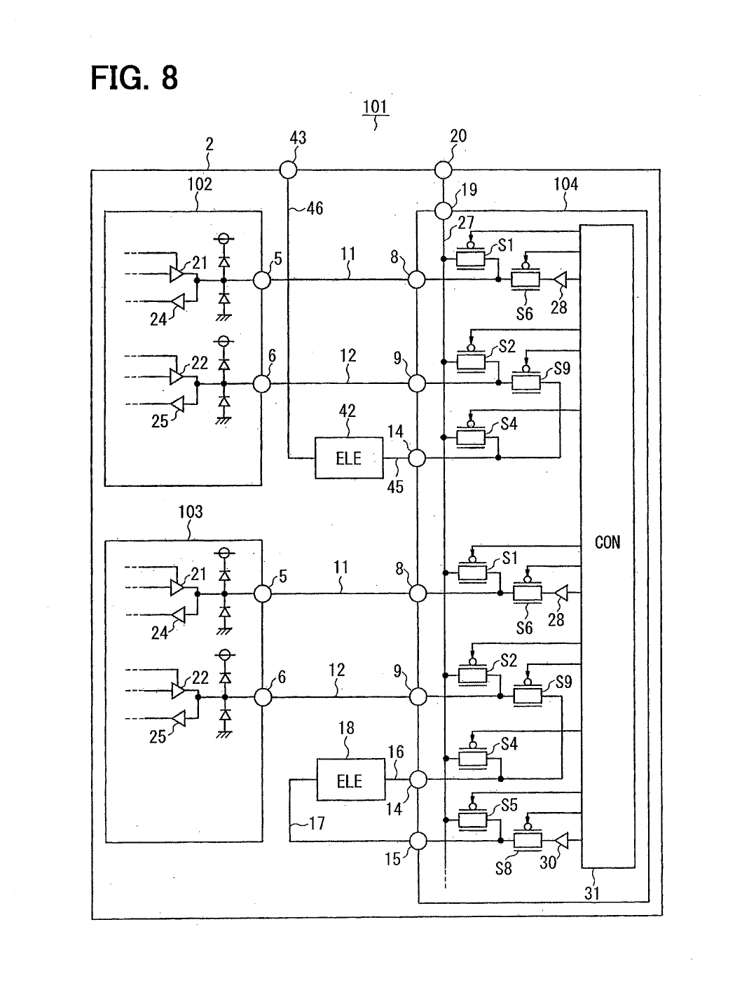

In the preceding embodiments, one target chip and one test chip are incorporated in the package 2. Alternatively, as shown in FIGS. 8, 9, and 10, each of the number of target chips and the number of test chips incorporated in the package 2 is not limited to one.

### First Example

FIG. 8 shows a semiconductor integrated circuit device 101 according to a first example of a sixth embodiment of the present disclosure. The semiconductor integrated circuit device 101 includes a semiconductor chip 102 as a target chip, a semiconductor chip 103 as a target chip, a semiconductor chip 104 as a test chip, and the electronic devices 18 and 42. The semiconductor chips 102 and 103 are configured in the same manner as, for example, the semiconductor chip 3 shown in FIG. 1. The semiconductor chip 104 has a test mechanism capable of performing an electrical test through each pad of the semiconductor chips 102 and 103.

The test mechanism of the semiconductor chip 104 are configured in the same manner as the test mechanism of the semiconductor chip 4 shown in FIG. 1 and the semiconductor chip 44 shown in FIG. 2. The common wire 27 of the test mechanism for the test of the pads 5 and 6 of the semiconductor chip 102 is connected to the common wire 27 of the test mechanism for the test of the pads 5 and 6 of the semiconductor chip 103. The common wires 27 are connected to a single external test terminal 20.

### Second Example

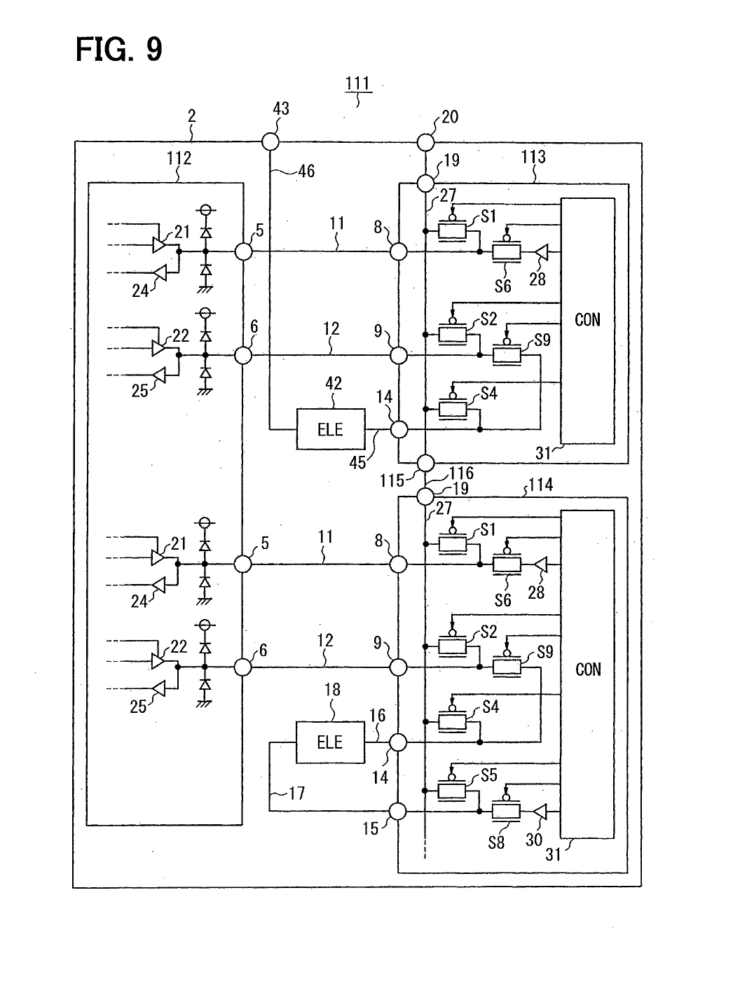

FIG. 9 shows a semiconductor integrated circuit device 111 according to a second example of the sixth embodiment. The semiconductor integrated circuit device 111 includes a semiconductor chip 112 as a target chip, a semiconductor chip 113 as a test chip, a semiconductor chip 104 as a test chip, and the electronic devices 18 and 42. The semiconductor chip 112 corresponds to an integration of the semiconductor chips 102 and 103 shown in FIG. 8 into one chip. The semiconductor chip 113 differs from the semiconductor chip 44 shown in FIG. 2 in that it further includes a pad 115. The semiconductor chip 114 is configured in the same manner as the semiconductor chip 4 shown in FIG. 1.

The pad 115 of the semiconductor chip 113 is connected to the test pad 19 of the semiconductor chip 114 through a wire 116. Thus, like the configuration shown in FIG. 8, the common wires 27 are connected to the single external test terminal 20.

### Third Example

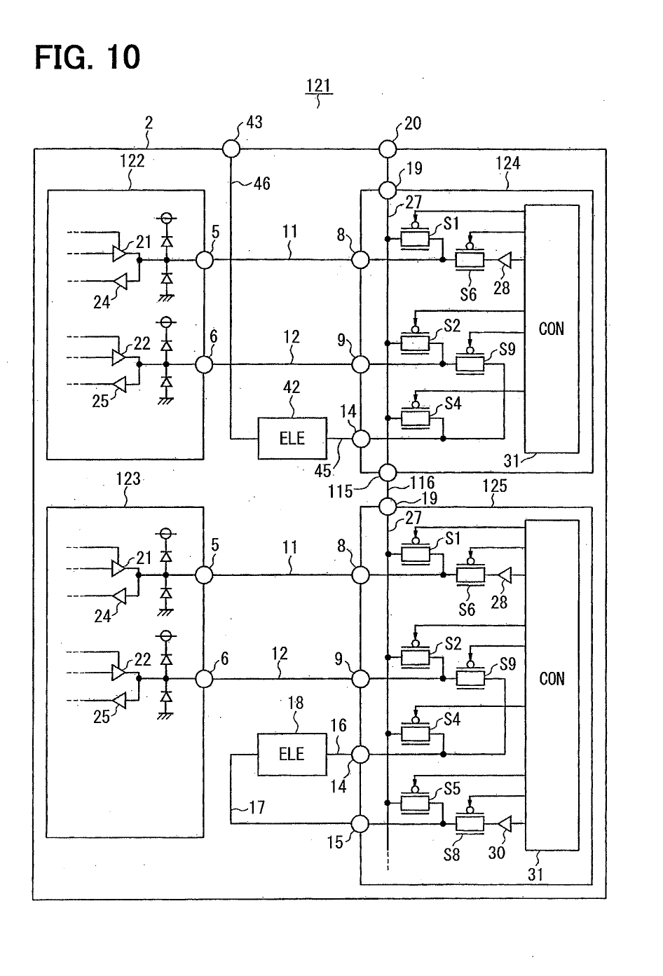

FIG. 10 shows a semiconductor integrated circuit device 121 according to a third example of the sixth embodiment. The semiconductor integrated circuit device 121 includes a semiconductor chip 122 as a target chip, a semiconductor chip 123 as a target chip, a semiconductor chip 124 as a test chip, a semiconductor chip 125 as a test chip, and the electronic devices 18 and 42. The semiconductor chips 122 and 123 are configured in the same manner as the semiconductor chips 102 and 103 shown in FIG. 8, respectively. The semiconductor chips 124 and 125 are configured in the same manner as the semiconductor chips 113 and 114 shown in FIG. 9, respectively. Thus, like the configurations shown in FIG. 8 and FIG. 9, the common wires 27 are connected to the single external test terminal 20.

Thus, according to the sixth embodiment, although the number of at least one of the target chip and the test chip incorporated into the single package 2 is two or more, the same advantages as in the first embodiment can be obtained while minimizing the number of the external test terminals.

### Seventh Embodiment

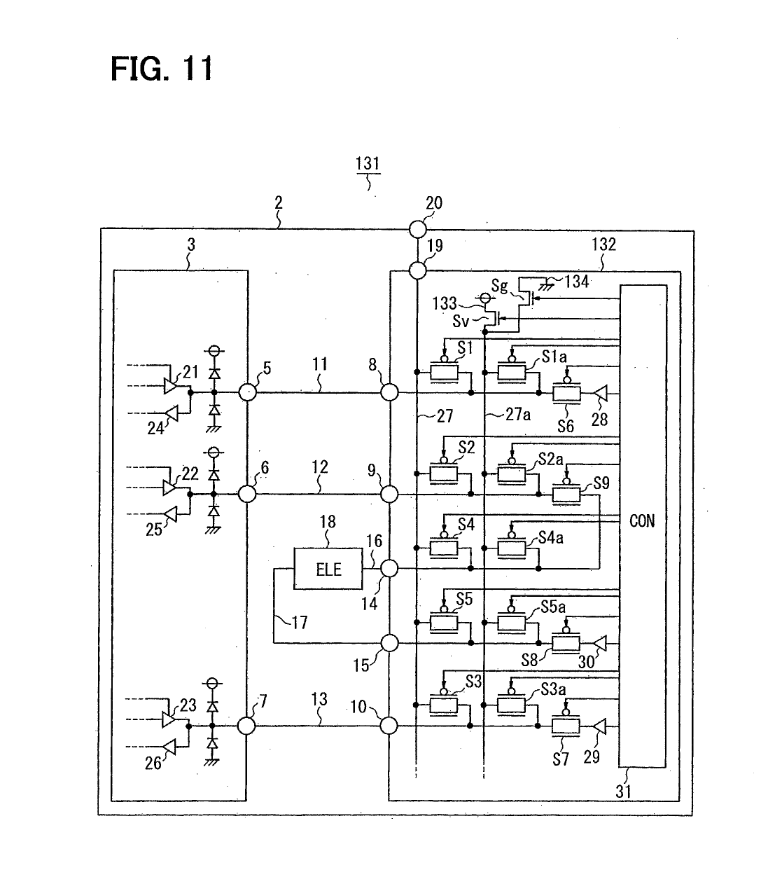

A semiconductor integrated circuit device 131 according to a seventh embodiment of the present disclosure is described below with reference to FIGS. 11, 12, and 13. The semiconductor integrated circuit device 131 differs from the semiconductor integrated circuit device 51 of the third embodiment as follows. The semiconductor integrated circuit device 131 has a semiconductor chip 132 instead of the semiconductor chip 52 as a test chip and does not have the external test terminal 53. The semiconductor chip 132 differs from the semiconductor chip 52 in that it has additional switches Sv and Sg but does not have the test pad 19a.

The common wire 27a is connected through the switch Sv to a power line 133 which is supplied with a power supply voltage inside the semiconductor chip 132. The common wire 27a is also connected through the switch Sg to a ground line 134 which is supplied with a ground potential inside the semiconductor chip 132. The switches Sv and Sg are semiconductor switching devices such as metal-oxide semiconductor (MOS) transistors and turned ON and OFF in accordance with driving signals received from the control circuit 31.

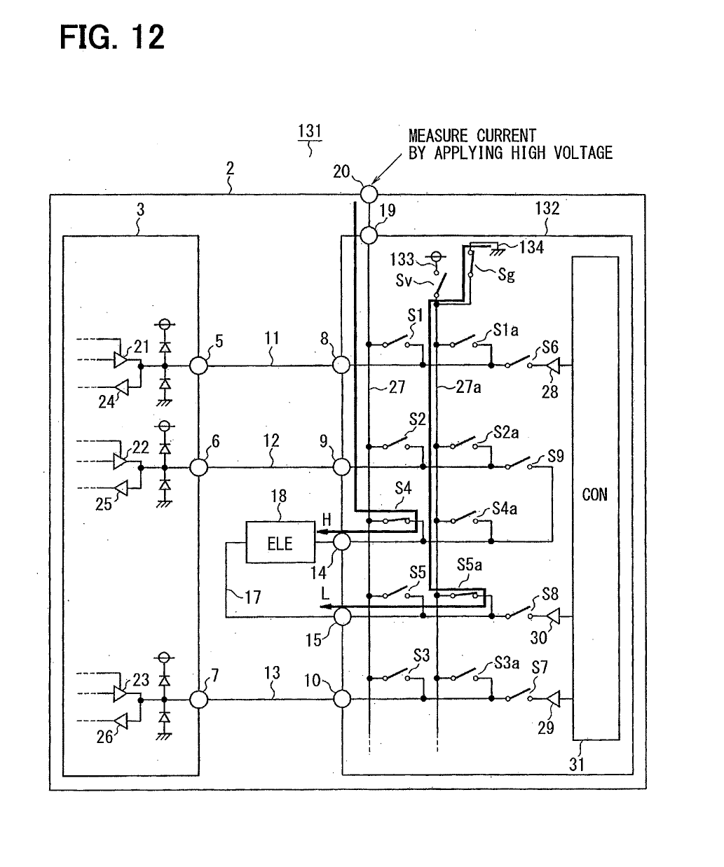

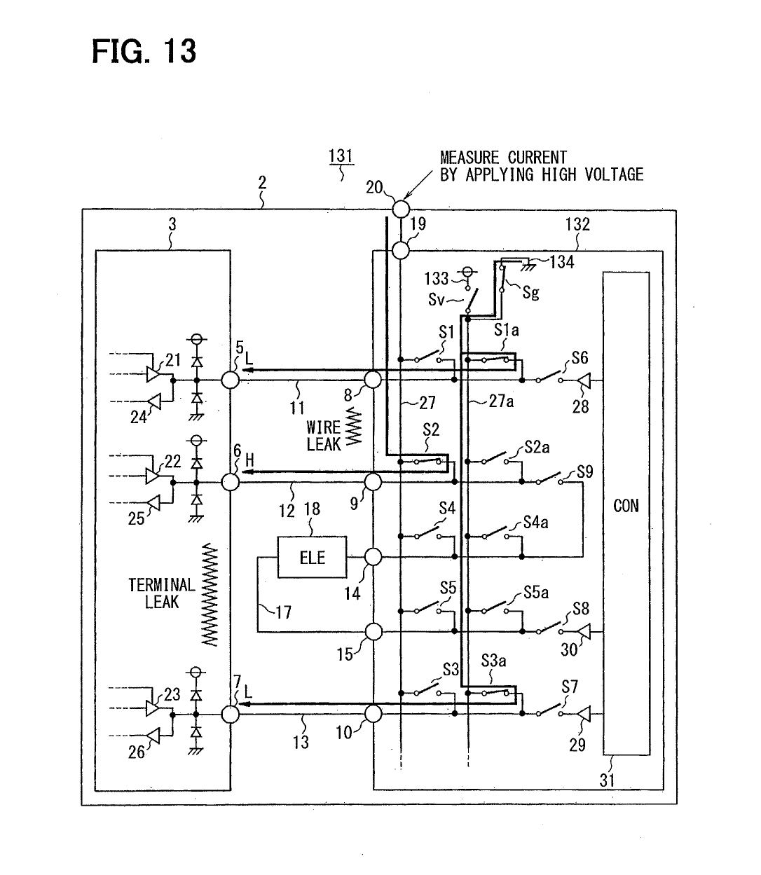

As shown in FIGS. 12 and 13, the semiconductor integrated circuit device 131 can be tested in the same manner as the semiconductor integrated circuit device 51 of the third embodiment. In FIGS. 12 and 13, the switches S1-S9, the switches S1a-S5a, and the switches Sv and Sg are denoted by symbols to indicate whether they are ON or OFF.

(1) A mode to perform a characteristic/functional test for the electronic device 18

When the characteristic/functional test for the electronic device 18 is performed, the control circuit 31 controls the switches as follows: The control circuit 31 turns ON the switches S4 and S5a (or S4a and S5) while turning OFF all the remaining switches connected to the common wires 27 and 27a. Besides, the control circuit 31 turns OFF the switches S8 and S9. In this case, each of the switches S6 and S7 can be either ON or OFF. Furthermore, the control circuit 31 turns OFF the switch Sv while turning OFF the switch Sg.

Under this condition, a current flowing through the external test terminal 20 is measured by applying a high voltage to the external test terminal 20 so that a high-level voltage (e.g., 5V) can be applied to the first terminal of the electronic device 18 and a low-level voltage (e.g., 0V) can be applied to the second terminal of the electronic device 18. Then, a resistance of the electronic device 18 is calculated based on the applied voltage and the measured current.

(1) A Mode to Perform a Leak Test Between Pads and Wires.

For example, when a leak test between the pads 6 and 7 and between the wires 12 and 13 and a leak test between pads 5 and 6, between the wires 11 and 12, and between the pads 8 and 9 are collectively performed, the control circuit 31 controls the switches as follows: The control circuit 31 turns ON the switches S1a, S2 and S1a (or S1, S2a, and S3) while turning OFF all the remaining switches connected to the common wires 27 and 27a Besides, the control circuit 31 turns OFF the switches S6, S7, and S9. In this case, the switch S8 can be either ON or OFF.

Under this condition, a current flowing through the external test terminal 20 is measured by applying a high voltage to the external test terminal 20 so that a high-level voltage (e.g., 5V) can be applied to one of the pads 6 and 7 (wires 12 and 13), a low-level voltage (e.g., 0V) can be applied to the other of the pads 6 and 7 (wires 12 and 13), the high-level voltage can be applied to one of the pads 5 and 6 (wires 11 and 12), and the low-level voltage can be applied to the other of the pads 5 and 6 (wires 11 and 12). Thus, a leak test for testing a leak current between the pads 6 and 7 and the wires 12 and 13 and a leak test for testing a leak current between the pads 5 and 6, the wires 11 and 12, and the pads 8 and 9 can be collectively performed based on the measured current.

### Eighth Embodiment

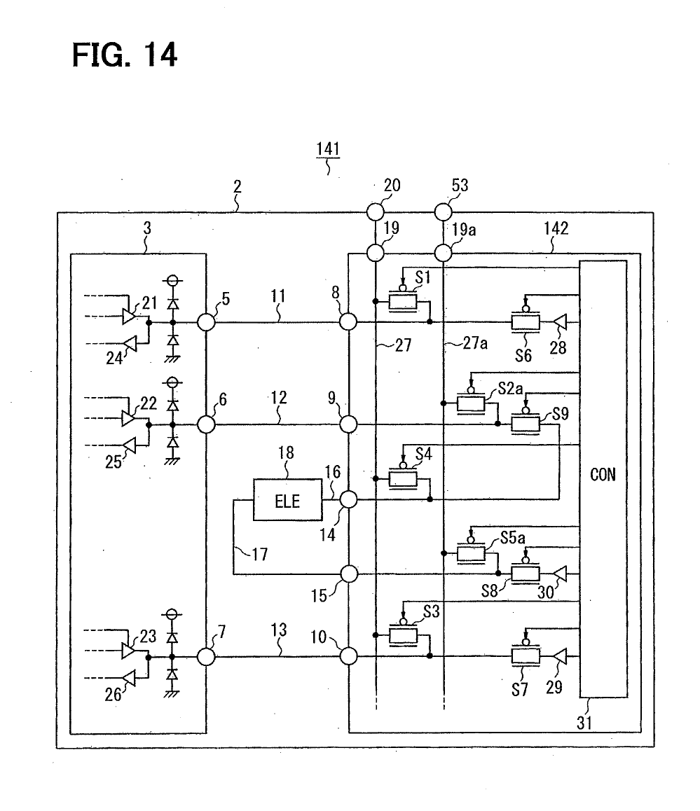

A semiconductor integrated circuit device 141 according to an eighth embodiment of the present disclosure is described below with reference to FIGS. 14, 15, and 16. The semiconductor integrated circuit device 141 differs from the semiconductor integrated circuit device 51 of the third embodiment as follows. The semiconductor integrated circuit device 141 has a semiconductor chip 142 instead of the semiconductor chip 52 as a test chip.

The semiconductor chip 142 differs from the semiconductor chip 52 in that it does not have the switches S1a, S2, S3a, S4a, and S5. One of two terminals (i.e., the pads 8 and 9, the pads 9 and 10) of the semiconductor chip 142 connected through wires to adjacent two terminals (i.e., the pads 5 and 6, the pads 6 and 7) of the semiconductor chip 3 is connected through the switch to the common wire 27, and the other of the two terminals is connected through the switch to the common wire 27a. One of two terminals (i.e., the pads 14 and 15) of the semiconductor chip 142 connected to the terminals of the electronic device 18 is connected through the switch to the common wire 27, and the other of the two terminals is connected through the switch to the common wire 27a.

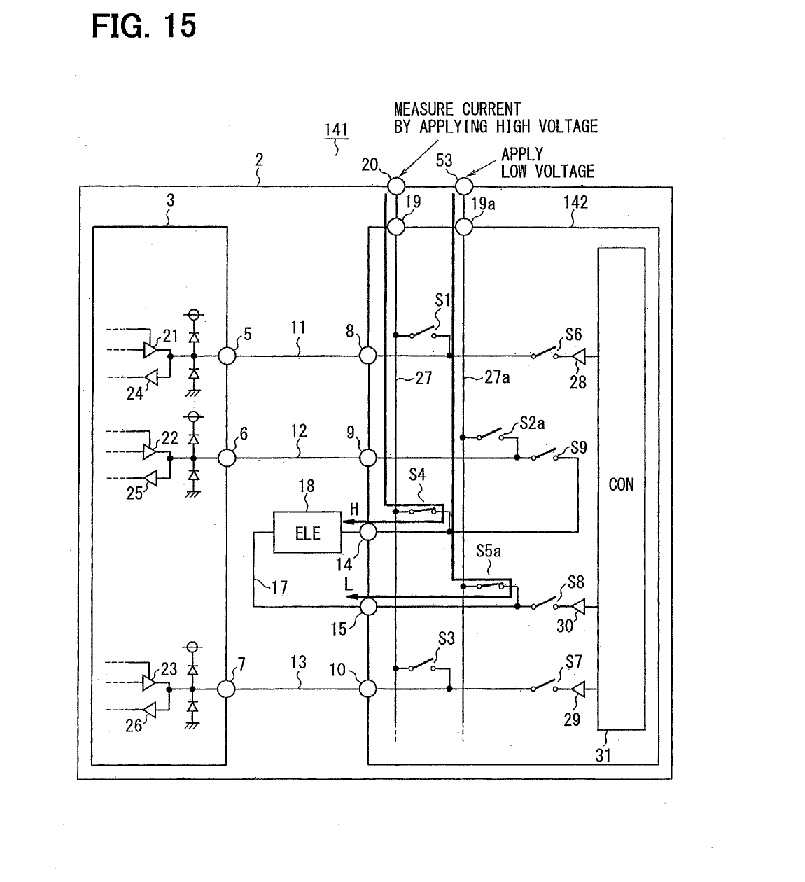

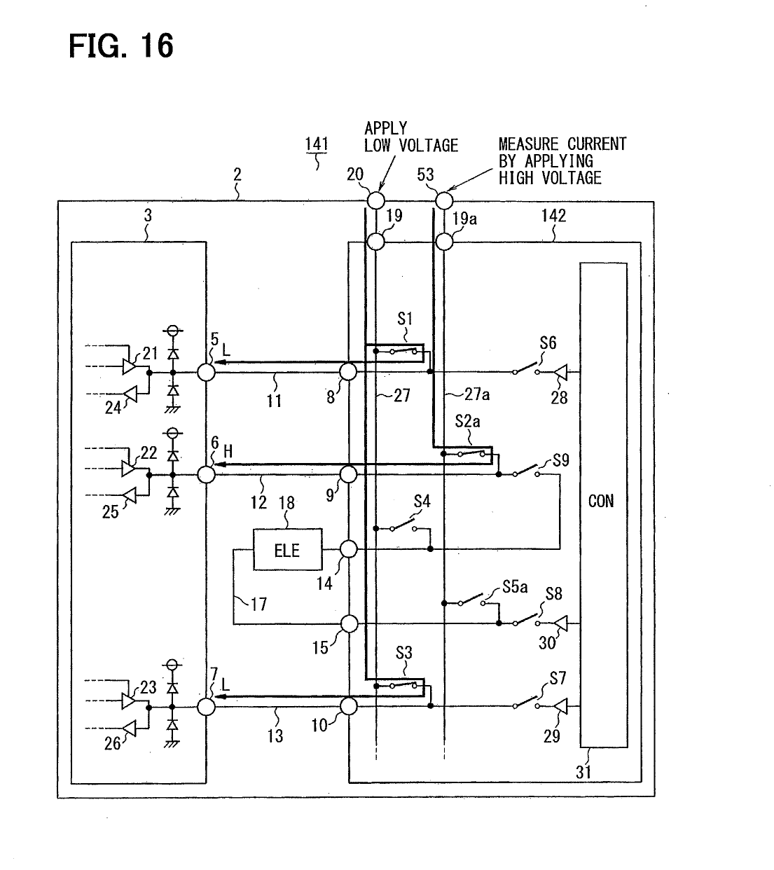

As shown in FIGS. 15 and 16, the semiconductor integrated circuit device 141 can be tested in the same manner as the semiconductor integrated circuit device 51 of the third embodiment. In FIGS. 15 and 16, like in FIGS. 12 and 13, the switches are denoted by symbols to indicate whether they are ON or OFF.

(1) A Mode to Perform a Characteristic/Functional Test for the Electronic Device 18

When the characteristic/functional test for the electronic device 18 is performed, the control circuit 31 controls the switches as follows: The control circuit 31 turns ON the switches S4 and S5a while turning OFF all the remaining switches connected to the common wires 27 and 27a. Besides, the control circuit 31 turns OFF the switches S8 and S9. In this case, each of the switches S6 and S7 can be either ON or OFF.

Under this condition, a current flowing through the external test terminals 20 and 53 is measured by applying a high voltage to one (the external test terminal 20 in an example of FIG. 15) of the external test terminals 20 and 53 while applying a low voltage to the other (the external test terminal 53 in the example of FIG. 15) of the external test terminals 20 and 53 so that a high-level voltage (e.g., 5V) can be applied to the first terminal of the electronic device 18 and a low-level voltage (e.g., 0V) can be applied to the second terminal of the electronic device 18. Then, a resistance of the electronic device 18 is calculated based on the applied voltage and the measured current.

(2) A Mode to Perform a Leak Test Between Pads and Wires.

For example, when a leak test between the pads 6 and 7 and between the wires 12 and 13 and a leak test between pads 5 and 6, between the wires 11 and 12, and between the pads 8 and 9 are collectively performed, the control circuit 31 controls the switches as follows: The control circuit 31 turns ON the switches S1, S2a, and S3 while turning OFF all the remaining switches connected to the common wires 27 and 27a. Besides, the control circuit 31 turns OFF the switches S6, S7, and S9. In this case, the switch S8 can be either ON or OFF.

Under this condition, a current flowing through the external test terminals 20 and 53 is measured by applying a high voltage to one (the external test terminal 53 in an example of FIG. 16) of the external test terminals 20 and 53 while applying a low voltage to the other (the external test terminal 20 in the example of FIG. 16) of the external test terminals 20 and 53 so that a high-level voltage (e.g., 5V) can be applied to one of the pads 6 and 7 (wires 12 and 13), a low-level voltage (e.g., 0V) can be applied to the other of the pads 6 and 7 (wires 12 and 13), the high-level voltage can be applied to one of the pads 5 and 6 (wires 11 and 12), and the low-level voltage can be applied to the other of the pads 5 and 6 (wires 11 and 12). Thus, a leak test for testing a leak current between the pads 6 and 7 and the wires 12 and 13 and a leak test for testing a leak current between the pads 5 and 6, the wires 11 and 12, and the pads 8 and 9 can be collectively performed based on the measured current.

In this way, the semiconductor integrated circuit device 141 can be tested in the same manner as the semiconductor integrated circuit device 51 of the third embodiment. Further, the number of the switches of the test chip of the semiconductor integrated circuit device 141 is smaller than that of the semiconductor integrated circuit device 51. Accordingly, the control circuit 31 for controlling the switches can be simplified, so that the semiconductor integrated circuit device 141 can be reduced in cost compared to the semiconductor integrated circuit device 51.

In the example shown in FIG. 14, the switches S1a, S2, S3a, S4a, and S5 are eliminated from the semiconductor chip 142. Alternatively, when the characteristic/functional test for the electronic device 18 is to be performed, the switches eliminated from the semiconductor chip 142 can be changed to satisfy the following condition (i): One of two terminals (i.e., the pads 14 and 15) of the semiconductor chip 142 connected to the terminals of the electronic device 18 is connected through the switch to the common wire 27, and the other of the two terminals is connected through the switch to the common wire 27a. And, when the leak test between pads and wires is to be performed, the switches eliminated from the semiconductor chip 142 can be changed to satisfy the following condition (ii): One of two terminals (i.e., the pads 8 and 9, the pads 9 and 10) of the semiconductor chip 142 connected through the wires (i.e., the wires 11-13) to adjacent two terminals (i.e., the pads 5 and 6, the pads 6 and 7) of the semiconductor chip 3 is connected through the switch to the common wire 27, and the other of the two terminals is connected through the switch to the common wire 27a. Therefore, for example, the switches S1, S2a, S3, S4, and S5a can be eliminated from the semiconductor chip 142 instead of the switches S1a, 52, S3a, S4a, and S5.

### Ninth Embodiment

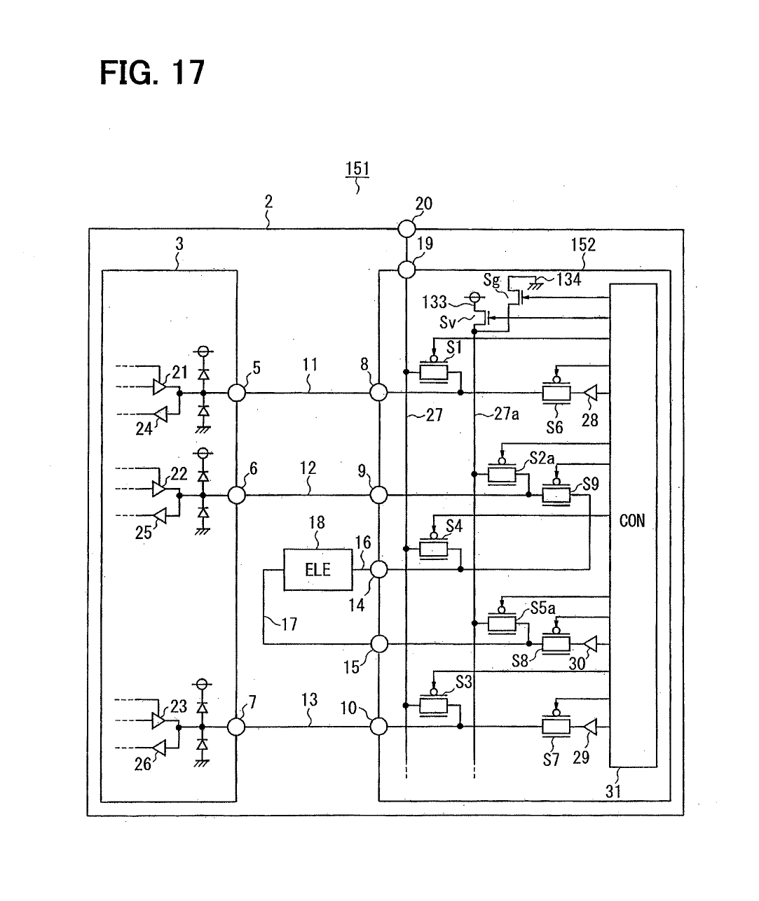

A semiconductor integrated circuit device 151 according to a ninth embodiment of the present disclosure is described below with reference to FIG. 17. The semiconductor integrated circuit device 151 differs from the semiconductor integrated circuit device 131 of the seventh embodiment as follows. The semiconductor integrated circuit device 151 has a semiconductor chip 152 instead of the semiconductor chip 132 as a test chip. The semiconductor chip 152 differs from the semiconductor chip 132 in that it does not have the switches S1a, S2, S3a, S4a, and S5.

The switches eliminated from the semiconductor chip 152 can be changed in the same manner as the semiconductor chip 142 of the eighth embodiment.

The semiconductor integrated circuit device 151 can be tested in the same manner as the semiconductor integrated circuit device 131 of the seventh embodiment. Further, like the semiconductor integrated circuit device 141 of the eighth embodiment, the semiconductor integrated circuit device 151 can be reduced in cost.

(Modification)

While the present disclosure has been described with reference to the embodiment, it is to be understood that the disclosure is not limited to the embodiment. The present disclosure is intended to cover various modifications and equivalent arrangements within the spirit and scope of the present disclosure.

The switch S4, 582 (corresponding to a third switch) for opening and closing a connection between the common wire 27, 27a and the pad 14, 88 (corresponding to a second terminal), to which the first terminal of the electronic device 18, 42, 62, 73, 92 is connected, is not always necessary. The switch S4, S82 can be omitted, for example, when application of voltage or current to the target pad 6, 84 is allowed or when there is no need to test the electronic device 18, 42, 62, 73, 92.

The switch 55, 571 (corresponding to a fourth switch) for opening and closing a connection between the common wire 27, 27a and the pad 15, 74 (corresponding to a signal terminal), to which the second terminal of the electronic device 18, 42, 62, 73, 92 is connected, is not always necessary. The switch S5, S71 can be omitted, for example, when there is no need to test the electronic device 18, 42, 62, 73, 92. If the switch S5, S71 is omitted, the switch S8, S72 for opening and closing a connection between the pad 15, 74 and an internal circuit of the test chip can be omitted by directly connecting the pad 15, 74 to the internal circuit.

In the embodiments, the test mechanism is provided near the output buffers 28-30 in the test chip. Alternatively, for example, the test mechanism can be provided near input buffers or input/output buffers in the test chip.

Such changes and modifications are to be understood as being within the scope of the present invention as defined by the appended claims.

What is claimed is:

1. A semiconductor integrated circuit device comprising:
a package;
a plurality of semiconductor chips incorporated in the package and having signal terminals connected to each other inside the package;
an electronic device incorporated in the package; and
a first external terminal extending from inside to outside the package, wherein
the plurality of semiconductor chips includes a target chip and a test chip,
the signal terminal of the target chip is a target terminal which is to be subjected to a test,
the test chip has a test mechanism capable of allowing the test to be performed through the first external terminal,
in a product operation mode where the semiconductor integrated circuit device operates as a product, a first terminal of the electronic device is connected to the target terminal,
the test chip includes a common wire, a first terminal, a first switch, a second terminal, a second switch, and a controller,
the common wire is connected to the test terminal,
the first terminal of the test chip is connected to the target terminal,
the first switch opens and closes a connection between the common wire and the first terminal of the test chip,
the second terminal of the test chip is connected to the first terminal of the electronic device,
the second switch opens and closes a connection between the first terminal of the test chip and the second terminal of the test chip, and
the controller controls the first switch and the second switch.

2. The semiconductor integrated circuit device according to claim 1, wherein
the test chip further includes a third switch configured to open and close a connection between the common wire and the second terminal of the test chip, and
the controller controls the third switch.

3. The semiconductor integrated circuit device according to claim 1, wherein
in the product operation mode, the first terminal of the electronic device is connected to the target terminal, and a second terminal of the electronic device is connected to the signal terminal of the test chip,
the test chip further includes a fourth switch and a fifth switch,
the fourth switch opens and closes a connection between the signal terminal of the test chip and the common wire,
the fifth switch opens and closes a connection between the signal terminal of the test chip and an internal circuit of the test chip, and
the controller controls the fourth switch and the fifth switch.

4. The semiconductor integrated circuit device according to claim 1, further comprising:
a second external terminal extending from inside to outside the package, wherein
in the product operation mode, the first terminal of the electronic device is connected to the target terminal, and a second terminal of the electronic device is connected to the second external terminal.

5. The semiconductor integrated circuit device according to claim 1, wherein
the electronic device includes a plurality of circuit elements,
the test chip further includes a third terminal, a sixth switch, and a seventh switch,
the plurality of circuit elements is connected in series through the third terminal and the sixth switch,
the seventh switch opens and closes a connection between the common wire and the third terminal, and
the controller controls the sixth switch and the seventh switch.

6. The semiconductor integrated circuit device according to claim 1, further comprising:
a plurality of common wires including the common wire.

7. The semiconductor integrated circuit device according to claim 3, further comprising:
a plurality of common wires including the common wire.

8. The semiconductor integrated circuit device according to claim 6, wherein
the plurality of common wires includes a predetermined common wire disconnected from the first external terminal,
the test chip further includes an eighth switch and a ninth switch,
the eighth switch opens and closes a connection between the predetermined common wire and an internal power source of the test chip, and
the ninth switch opens and closes a connection between the predetermined common wire and an internal ground of the test chip.

9. The semiconductor integrated circuit device according to claim 6, wherein
the plurality of common wires includes a first common wire and a second common wire different from the first common wire,
each of the target chip and the test chip has a plurality of signal terminals,
two of the plurality of signal terminals of the test chip are connected to adjacent two signal terminals of the target chip,
one of the two of the plurality of signal terminals of the test chip is connected to the first common wire through at least one of the switches included in the test chip, and
the other of the two of the plurality of signal terminals of the test chip is connected to the second common wire.

10. The semiconductor integrated circuit device according to claim 6, wherein
the plurality of common wires includes a first common wire and a second common wire different from the first common wire,
the test chip has two signal terminals connected to the electronic device,
one of the two signal terminals of the test chip is connected to the first common wire through at least one of the switches included in the test chip, and
the other of the two signal terminals of the test chip is connected to the second common wire.

11. The semiconductor integrated circuit device according to claim 7, wherein
the plurality of common wires includes a predetermined common wire disconnected from the first external terminal,
the test chip further includes an eighth switch and a ninth switch,
the eighth switch opens and closes a connection between the predetermined common wire and an internal power source of the test chip, and
the ninth switch opens and closes a connection between the predetermined common wire and an internal ground of the test chip.

12. The semiconductor integrated circuit device according to claim 7, wherein
the plurality of common wires includes a first common wire and a second common wire different from the first common wire,
each of the target chip and the test chip has a plurality of signal terminals,
two of the plurality of signal terminals of the test chip are connected to adjacent two signal terminals of the target chip,
one of the two of the plurality of signal terminals of the test chip is connected to the first common wire through at least one of the switches included in the test chip, and
the other of the two of the plurality of signal terminals of the test chip is connected to the second common wire.

13. The semiconductor integrated circuit device according to claim 7, wherein
the plurality of common wires includes a first common wire and a second common wire different from the first common wire,
the test chip has two signal terminals connected to the electronic device,
one of the two signal terminals of the test chip is connected to the first common wire through at least one of the switches included in the test chip, and
the other of the two signal terminals of the test chip is connected to the second common wire.

14. The semiconductor integrated circuit device according to claim 1, wherein
the target chip has a plurality of target terminals including the target terminal,
the test chip has a plurality of common wires including the common wire,
each of the plurality of target terminals is provided to a corresponding one of the plurality of common wires, and
the plurality of common wires is connected together to the first external terminal.
